(19) United States
(12) Patent Application Publication
(10) Pub. No.: US 2026/0164657 A1
(43) Pub. Date: Jun. 11, 2026

(54) THREE-DIMENSIONAL SEMICONDUCTOR MEMORY DEVICE AND METHOD OF FABRICATING THE SAME

(71) Applicant: SK hynix Inc., Gyeonggi-do (KR)

(72) Inventors: Sungwon LIM, San Jose, CA (US); Dengtao ZHAO, San Jose, CA (US); Sung-Taeg KANG, San Jose, CA (US)

(21) Appl. No.: 18/969,266

(22) Filed: Dec. 5, 2024

(51) Int. Cl. H10B 43/27; H10B 43/35

(52) U.S. Cl. CPC H10B 43/27; H10B 43/35

(57) ABSTRACT

There are provided a method of fabricating a three-dimensional semiconductor memory device and a semiconductor memory device. The three-dimensional semiconductor memory device may include: a plurality of interlayer insulating layers and a plurality of gate electrodes, which are alternately stacked to form a stack structure; and a channel vertically disposed within the stack structure. Each of gate electrodes disposed in at least one of a source select transistor area and a drain select transistor area, among the plurality of gate electrodes includes a first metal and a second metal. Each of gate electrodes disposed in a memory cell area, among the plurality of gate electrodes includes the second metal. The first metal has a work function lower than a work function of the second metal.

### BACKGROUND

### 1. Technical Field

Embodiments of the present disclosure relate to a semiconductor memory device, and more particularly to a three-dimensional semiconductor memory device and a method of fabricating a three-dimensional semiconductor memory device.

### 2. Related Art

Semiconductor memory devices may include a plurality of memory cells capable of storing data. In order to improve a degree of integration of semiconductor memory devices, three-dimensional (3D) memory devices in which memory cells are arranged in three-dimensions on a substrate have been proposed.

In this context, embodiments of the present disclosure arise.

### SUMMARY

Embodiments of the present disclosure are directed to a three-dimensional semiconductor memory device capable of securing a strong gate-induced drain leakage (GIDL) during an erase operation by modulating a work function of gate metal, and a method of fabricating a three-dimensional semiconductor memory device.

In accordance with an embodiment of the present disclosure, there is provided a method of fabricating a three-dimensional semiconductor memory device. The method may include: forming first interlayer insulating layers and first sacrificial layers alternately stacked on a substrate to form a first stack structure, while forming first metal layers having a first work function at interfaces between the first interlayer insulating layers and the first sacrificial layers; forming a second interlayer insulating layers and a second sacrificial layers alternately stacked on the first stack structure to form a second stack structure; forming a third interlayer insulating layers and a third sacrificial layers alternately stacked on the second stack structure to form a third stack structure, while forming second metal layers having the first work function at interfaces between the third interlayer insulating layers and the third sacrificial layers; forming a channel hole penetrating the first to third stack structures; forming a memory layer and a channel layer in the channel hole; and replacing the first to third sacrificial layers with third metal layers having a second work function higher than the first work function.

In accordance with an embodiment of the present disclosure, there is provided a three-dimensional semiconductor memory device. The three-dimensional semiconductor memory device may include: a plurality of interlayer insulating layers and a plurality of gate electrodes, which are alternately stacked to form a stack structure; and a channel vertically disposed within the stack structure. Each of gate electrodes disposed in at least one of a source select transistor area and a drain select transistor area, among the plurality of gate electrodes includes a first metal and a second metal. Each of gate electrodes disposed in a memory cell area, among the plurality of gate electrodes includes the second metal. The first metal has a work function lower than a work function of the second metal.

In accordance with an embodiment of the present disclosure, there is provided a method of fabricating a three-dimensional semiconductor memory device. The method may include: forming first interlayer insulating layers and first sacrificial layers alternately stacked on a substrate to form a first stack structure, while forming first metal layers having a first work function at interfaces between the first interlayer insulating layers and the first sacrificial layers; forming a second interlayer insulating layers and a second sacrificial layers alternately stacked on the first stack structure to form a second stack structure; forming a channel hole penetrating the first and second stack structures; forming a memory layer and a channel layer in the channel hole; and replacing the first and second sacrificial layers with second metal layers having a second work function higher than the first work function.

In accordance with an embodiment of the present disclosure, there is provided a method of fabricating a three-dimensional semiconductor memory device. The method may include: forming first interlayer insulating layers and first sacrificial layers alternately stacked on a substrate to form a first stack structure; forming second interlayer insulating layers and second sacrificial layers alternately stacked on a substrate to form a second stack structure, while forming first metal layers having a first work function at interfaces between the second interlayer insulating layers and the second sacrificial layers; forming a channel hole penetrating the first and second stack structures; forming a memory layer and a channel layer in the channel hole; and replacing the first and second sacrificial layers with second metal layers having a second work function higher than the first work function.

These and other features and advantages of the embodiments of the present disclosure will become apparent to those skilled in the art from the following detailed description in conjunction with the following drawings.

### BRIEF DESCRIPTION OF THE DRAWINGS

FIG. 1 is a schernatic circuit diagram illustrating a memory cell string of a semiconductor memory device.

FIG. 2 is a perspective view illustrating a structure of a semiconductor memory device.

FIG. 3 is a conceptual view illustrating a semiconductor memory device in accordance with an embodiment of the present disclosure.

FIG. 4 is a graph illustrating a GIDL current with reference to a gate electrode work function.

FIG. 5A is a graph illustrating a work function with reference to metals.

FIG. 5B is a table showing a work function with reference to metals with or without Lanthanum (La).

FIGS. 6A to 6D are cross-sectional views illustrating a method of fabricating a three-dimensional semiconductor memory device, in accordance with an embodiment of the present disclosure.

### DETAILED DESCRIPTION

Various embodiments of the present disclosure will be described in greater detail with reference to the accompanying drawings. The drawings are schematic illustrations of various embodiments and intermediate structures. As such, variations from the configurations and shapes of the illustrations as a result, for example, of manufacturing techniques and/or tolerances, are to be expected. Thus, the described embodiments should not be construed as being limited to the particular configurations and shapes illustrated herein but may include deviations in configurations and shapes which do not depart from the spirit and scope of the present disclosure as defined in the appended claims.

The embodiments of the present disclosure are described herein with reference to cross-section and/or plan illustrations of the embodiments. However, the embodiments of the present disclosure should not be construed as limiting the inventive concept. Although a few embodiments of the present disclosure will be shown and described, it will be appreciated by those of ordinary skill in the art that changes may be made in these embodiments without departing from the principles and spirit of the present disclosure.

It will be understood that, although the terms “first”, “second”, “third”, and so on may be used herein to describe various elements, these elements are not limited by these terms. These terms are used to distinguish one element from another element. Thus, a first element described below could also be termed as a second or third element without departing from the spirit and scope of the present disclosure.

It will be further understood that when an element is referred to as being “connected to”, or “coupled to” another element, it may be directly on, connected to, or coupled to the other element, or one or more intervening elements may be present. Furthermore, the connection/coupling may not be limited to a physical connection but may also include a non-physical connection, e.g., a wireless connection.

In addition, it will also be understood that when an element is referred to as being “between” two elements, it may be the only element between the two elements, or one or more intervening elements may also be present.

When a first element is referred to as being “over” a second element, it not only refers to a case where the first element is formed directly on the second element but also a case where a third element exists between the first element and the second element. When a first element is referred to as being “on” a second element, it refers to a case where the first element is formed directly or indirectly on the second element or the substrate.

It should be understood that the drawings are simplified schematic illustrations of the described devices and may not include well known details to avoid obscuring the features of the embodiments.

It should also be noted that features present in one embodiment may be used with one or more features of another embodiment without departing from the scope of the present disclosure.

It is further noted, that in the various drawings, like reference numbers designate like elements.

As used herein, singular forms are intended to include the plural forms as well, unless the context clearly indicates otherwise.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the continuous structure. For example, a layer may be located between any pair of horizontal planes between, or at, a top surface and a bottom surface of the continuous structure. A layer may extend horizontally, vertically, and/or along a tapered surface. A substrate may be a layer, may include one or more layers therein, or may have one or more layer thereupon, thereabove, and/or therebelow.

As used herein, a first surface and a second surface are “vertically coincident” with each other if the second surface overlies or underlies the first surface and there exists a vertical plane or a substantially vertical plane that includes the first surface and the second surface. A substantially vertical plane is a plane that extends straight along a direction that deviates from a vertical direction by an angle less than 5 degrees. A vertical plane or a substantially vertical plane is straight along a vertical direction or a substantially vertical direction, and may, or may not, include a curvature along a direction that is perpendicular to the vertical direction or the substantially vertical direction.

A package or a chip may include a single semiconductor die (or a “die”) or a plurality of semiconductor dies. A die is the smallest unit that can independently execute external commands or report status. Each die includes one or more planes. Identical concurrent operations can be executed in each plane within a same die. In a memory die, each plane contains a number of memory blocks (or “blocks”), which are the smallest units that can be erased in a single erase operation. Each memory block contains a number of pages, which are the smallest units that can be selected for programming. A page is also the smallest unit that can be selected in a read operation. A memory block includes a plurality of memory cells, which are coupled to a number of word lines (i.e., rows) and a number of bit lines (i.e., columns).

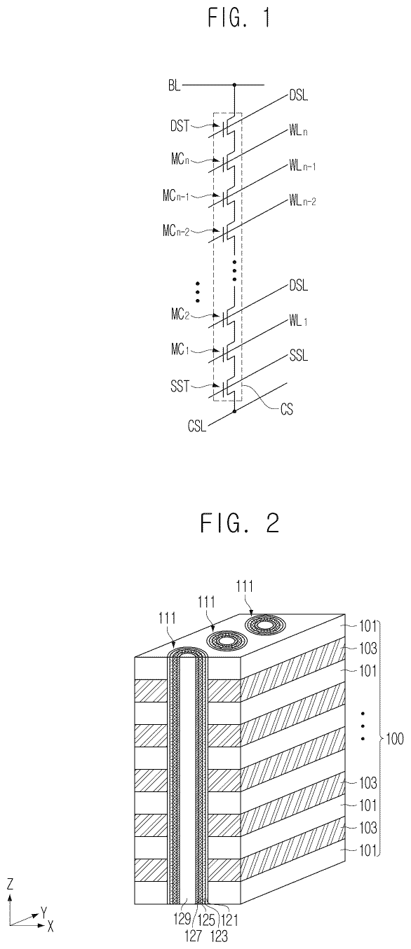

FIG. 1 is a schernatic circuit diagram illustrating a memory cell string of a semiconductor memory device. In FIG. 1, a configuration of a memory cell string CS of a three-dimensional NAND device is illustrated.

Referring to FIG. 1, the memory cell string CS may be coupled to a bit line BL and a common source line CSL. Although a single memory cell string CS is illustrated, a plurality of memory cell strings may be coupled in parallel between the bit line BL and the common source line CSL.

The memory cell string CS may include a source select transistor SST, a plurality of memory cells MC1 to MCn, and a drain select transistor DST connected in series between the common source line CSL and the bit line BL.

The source select transistor SST may control the electrical connection between the common source line CSL and the memory cells MC1 to MCn. The source select transistor SST may be coupled to a source select line SSL, and controlled by a source gate signal (voltage) applied to the source select line SSL. Although one source select transistor SST is illustrated in FIG. 1, two or more source select transistors may be disposed in series between the common source line CSL and the memory cells MC1 to MCn.

The memory cells MC1 to MCn may be coupled in series between the source select transistor SST and the drain select transistor DST. The memory cells MC1 to MCn may be coupled to a plurality of word lines WL1 to WLn, and controlled by cell gate signals (voltages) applied to the word lines WL1 to WLn. Each of the memory cells MC1 to MCn may store single-bit data or multi-bit data.

The drain select transistor DST may control the electrical connection between the memory cells MC1 to MCn and the bit line BL. The drain select transistor DST may be coupled to a drain select line DSL, and controlled by a drain gate signal (voltage) applied to the drain select line DSL. Although one drain select transistor DST is illustrated in FIG. 1, two or more source select transistors may be disposed in series between the bit line BL and the memory cells MC1 to MCn.

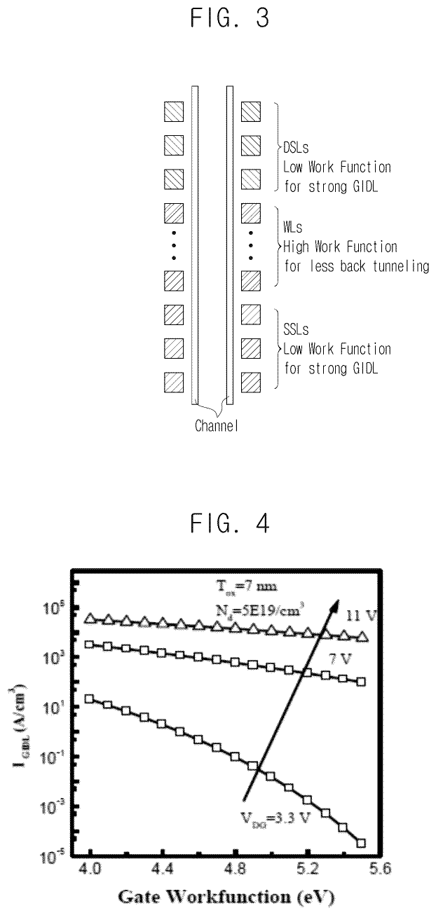

FIG. 2 is a perspective view illustrating a structure of a semiconductor memory device. In FIG. 2, a partially exploded structure of a three-dimensional NAND device is illustrated.

Referring to FIG. 2, the semiconductor memory device may include a stacked body 100, a blocking insulating layer 121, a data storage layer 123, a tunnel insulating layer 125, and a channel layer 127. The semiconductor memory device may further include a gap-filling layer 129.

The stacked body 100 may include interlayer insulating layers 101 and gate electrodes 103. Each of the interlayer insulating layers 101 and the gate electrodes 103 may be parallel to an X-Y plane. The interlayer insulating layers 101 and the gate electrodes 103 may be stacked in a Z-axis direction perpendicular to the X-Y plane. The interlayer insulating layers 101 and the lines 103 may be alternately stacked.

The interlayer insulating layers 101 may be formed of silicon oxide (e.g., SiO₂).

The gate electrodes 103 may be insulated from each other by the interlayer insulating layers 101. The gate electrodes 103 may be used as the word lines WL1 to WLn, the source select line SSL, and the drain select line DSL described with reference to FIG. 1. The gate electrodes 103 may be formed of doped semiconductor, metal, metal nitride, and metal silicide. For example, the gate electrodes 103 may be formed of a multiple layer of titanium nitride (TiN)/Tungsten (W).

The stacked body 100 may be penetrated by a channel hole 111 extending in the Z-axis direction during the fabrication process. The interlayer insulating layers 101 and the gate electrodes 103 may be defined along a sidewall of the channel hole 111. The channel hole 111 may have various shapes, such as a circle, an oval, a square, a rectangle, and a polygon.

The channel layer 127 may be formed of semiconductor, such as poly-silicon or the like. The channel layer 127 may extend in the Z-axis direction along the sidewall of the channel hole 111. The channel layer 127 may form a channel area of the memory cell string CS illustrated in FIG. 1.

The blocking insulating layer 121, the data storage layer 123, and the tunnel insulating layer 125 may be interposed between the stacked body 100 and the channel layer 127. The blocking insulating layer 121, the data storage layer 123, and the tunnel insulating layer 125 may be referred to as a memory layer or an ONO layer.

The blocking insulating layer 121 may include a single layer or multiple layers. The blocking insulating layer 121 may include a silicon oxide layer or a silicon oxide/metal oxide layer. The metal oxide layer (e.g., aluminum oxide, Al₂O₃) may have a higher dielectric constant (i.e., high-k) than that of the silicon oxide layer.

The data storage layer 123 may include a silicon nitride layer (e.g., Si₃N₄). The data storage layer 123 may be referred to as a charge trap layer.

The tunnel insulating layer 125 may include an oxide layer (e.g., silicon oxide, SiO₂) or metal organic frameworks (MOF).

The channel layer 127, the tunnel insulating layer 125, the data storage layer 123, and the blocking insulating layer 121 may be formed in various structures.

In the illustrated embodiment of FIG. 2, the blocking insulating layer 121, the data storage layer 123, and the tunnel insulating layer 125 may extend in the Z-axis direction along the sidewall of the channel layer 127. However, at least one of the blocking insulating layer 121, the data storage layer 123, and the tunnel insulating layer 125 may be disposed in pocket areas in which the gate electrodes 103 are recessed.

Meanwhile, in order to increase the integration in a three-dimensional NAND device, various scaling schemes have been developed. For example, the scaling schemes include a logical scaling (e.g., a single-level cell (SLC), a multi-level cell (MLC), a triple-level cell (TLC), a quad-level cell (QLC), a penta-level cell (PLC)), a vertical scaling (e.g., 100 stacks (tiers), 200 stacks, 300 stacks, 400 stacks), a lateral scaling (e.g., 3 rows between a slit to a slit as one block, 9 rows, 19 rows, in which higher rows mean higher density), and a structural scaling (e.g., 4 dimension (4D), Periphery under Cell Array (PUA), Hybrid Wafer Bonding (HWB)).

These schemes reached their limits in terms of physical and cost issues. To overcome the limitations, additional physical scaling methods are being developed through the formation of multiple cells. For example, schemes of fabricating multiple cells based on the cutting of channel area are under consideration. Such schemes are referend to as a multi-site cells or multi-slit cells (MSC).

As noted above, the gate electrodes 103 may be formed of metal, and used as the word lines WL1 to WLn, the source select lines SSLs, and the drain select line DSLs described with reference to FIG. 1.

For example, when a multiple layer of TiN/W is applied to the gate electrodes 103 and Al₂O₃ is applied to the blocking insulating layer 121, due to the band bending through Al₂O₃ and TiAlN formation at the interface, electrons that are back tunneled during an erase operation are minimized. Further, Molybdenum (Mo) and Ruthenium (Ru), which have lower resistance, have been evaluated as an alternative metal material for the gate electrodes 103. However, there has not yet been a sufficient review of the process improvement for improving the erase and program characteristics using these alternative metals.

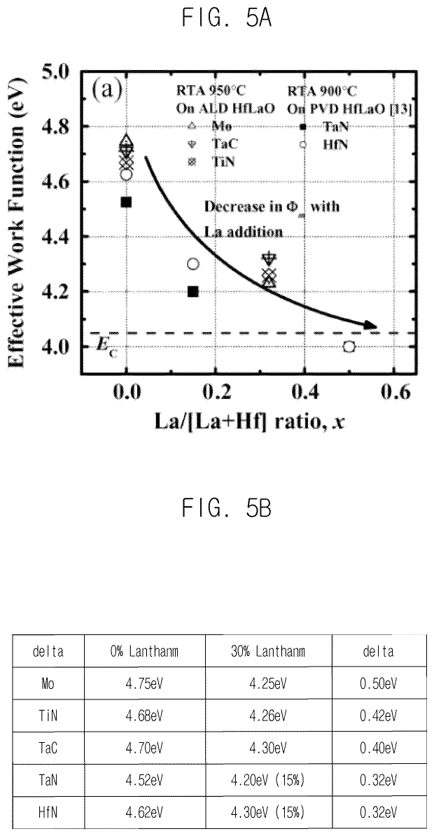

FIG. 3 is a conceptual view illustrating a semiconductor memory device in accordance with an embodiment of the present disclosure. In FIG. 3, a conceptual configuration of a memory cell string of a three-dimensional NAND device is illustrated.

Referring to FIG. 3, the memory cell string may include at least one source select transistor, a plurality of memory cells, and at least one drain select transistor connected in series between a common source line and a bit line. In the figure, a channel, source select lines SSLs, word lines WLs, and drain select lines DSLs are merely illustrated.

When the same metal electrode layers (e.g., TiN/W) are applied to the source select lines SSLs, the drain select lines DSLs, and the word lines WLs, electrons that are back-tunneled during an erase operation can be minimized in the memory cells, due to a high work function of the metal electrode layers. However, the high work function of the metal electrode layers renders a strong GIDL generation during an erase operation impossible in the source/drain select transistors.

In an embodiment of the present disclosure, the word lines WLs may contain a fist metal having a high work function for less back-tunneled electrons during an erase operation, and the source select lines SSLs and the drain select lines DSLs may contain a second metal having a low work function for strong GIDL generation during an erase operation.

For example, the fist metal having a high work function may include one of TiN, TiAlN, TiN/W, TaN, HfN, Molybdenum (Mo), and Ruthenium (Ru), and the second metal having a low work function may include the above metals used in the first metal and a metal (or material) with a low work function. Such metal (or material) with a low work function may include Lanthanum (La), La-containing material, molybdenum nitride (MoN), or MoN-containing material, which is added as auxiliary metal and has a work function as low as 0.4 eV to 0.5 eV compared to a work function of the first metal.

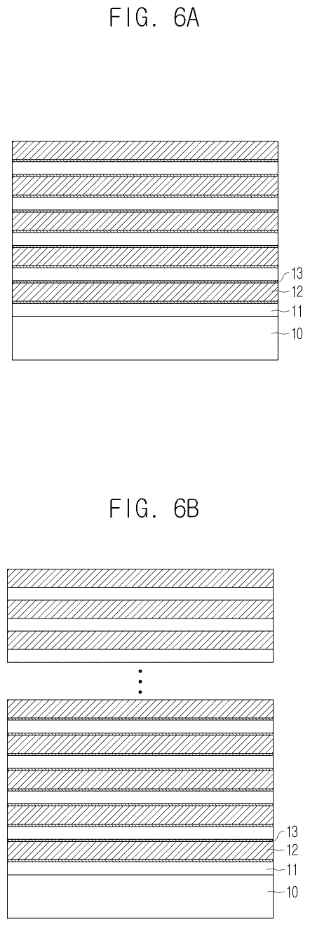

As shown in FIG. 4, the GIDL current increases as a gate electrode work function is lowered (refer to Journal of Electron Devices, Vol. 13, 2012, pp. 984-996). That is, strong GIDL generation can be secured when a gate electrode work function is low.

Basically, a leakage current between a drain and a bulk (i.e., substrate or well region) is generated due to electron-hole pairs generated by tunneling of valence band electrons into a conduction band. The GIDL is induced by the band-to-band tunneling (BTBT) effect in a strong accumulation mode, and generated in a gate-to-drain overlap region. The GIDL may be increased by increasing band bending through the lower work function of a gate electrode.

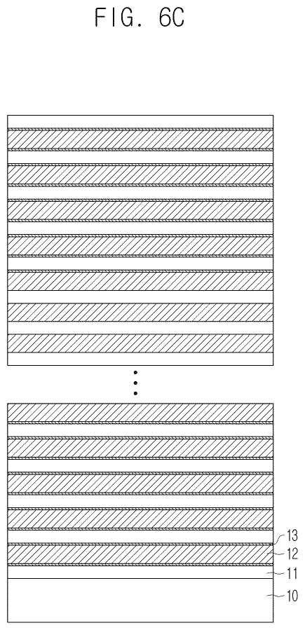

As shown in FIGS. 5A and 5B, if Lanthanum (La) is added by about 30%, the gate electrode work function can be lowered by 0.4 eV to 0.5 eV even in a case where TiN or Molybdenum is used as a gate electrode. That is, when the low gate electrode work function can be selectively applied to the source/drain select lines SSLs/DSLs where the GIDL generation occurs during an erase operation, it is possible to improve the erase and program characteristics (refer to IEEE ELECTRON DEVICE LETTERS, VOL. 29, NO. 8, AUGUST 2008).

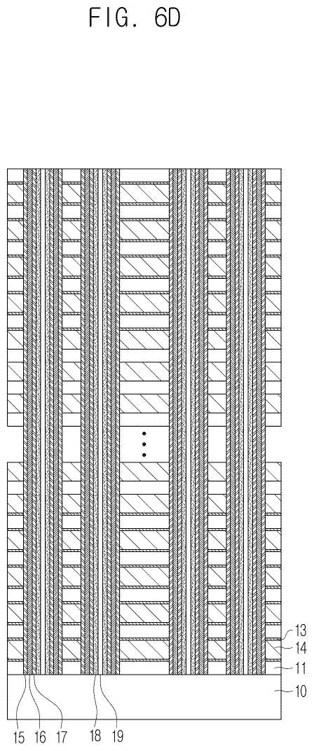

FIGS. 6A to 6D are cross-sectional views illustrating a method of fabricating a three-dimensional semiconductor memory device, in accordance with an embodiment of the present disclosure.

Referring to FIG. 6A, interlayer insulating layers 11, first metal layers 13, and sacrificial layers 12 may be alternately deposited on a substrate 10 to form a first stack structure.

In the first stack structure, the first metal layers 13 may be formed at every interfaces between interlayer insulating layers 11 and the sacrificial layers 12.

The number of stacks of the interlayer insulating layers 11 and the sacrificial layers 12 may correspond to the number of source select transistors included in a single cell string (see FIG. 1). Although the number of source select transistors may be 5 in the illustrated embodiment, the embodiments of the present disclosure are not limited thereto.

The substrate 10 may include a silicon wafer. The substrate 10 may further include various elements and interlayer insulating layers formed thereon.

Each of the interlayer insulating layers 11 may include an oxide layer (e.g., SiO₂).

Each of the sacrificial layers 12 may include a nitride layer (e.g., SiN). The thickness of the sacrificial layers 12 may correspond to the thickness of gate electrodes (e.g., WLs, SSLs, DSLs). For example, the thickness of each of the sacrificial layers 12 may be 20 nm to 25 nm.

The first metal layers 13 may have a low work function. For example, the first metal layers 13 may include Lanthanum (La) or La-containing material. The Lanthanum (La) or La-containing material may have a work function as low as 0.4 ev to 0.5 eV compared to a work function of a metal used for word lines WLs (i.e., second metal layers). Further, the thickness of each of first metal layers 13 may be inm to 2 nm, and Lanthanum (La) ratio in the first metal layers 13 may be 25% to 30%.

In some embodiments, while alternately depositing the interlayer insulating layers 11 and the sacrificial layers 12 in a chamber using a plasma-enhanced chemical vapor deposition (PECVD) deposition method, Lanthanum (La) may be additionally doped at interfaces between the interlayer insulating layers 11 and the sacrificial layers 12. The Lanthanum (La) may exist at the interface in a form of lanthanum oxide (La₂O₃), and after replacing the sacrificial layers 12 with gate electrodes, the La atoms included therein may play a role in lowering a work function of the gate electrodes as much as 0.4 eV to 0.5 eV.

In some embodiments, molybdenum nitride (MoN) or MoN-containing material may be used as the first metal layers 13.

Referring to FIG. 6B, the interlayer insulating layers 11 and the sacrificial layers 12 may be alternately deposited on the first stack structure to form a second stack structure.

The number of stacks of the interlayer insulating layers 11 and the sacrificial layers 12 may correspond to the number of memory cells included in a single cell string (see FIG. 1).

In some embodiments, the interlayer insulating layers 11 and the sacrificial layers 12 may be alternately deposited in the same chamber used to form the first stack structure.

Referring to FIG. 6C, the interlayer insulating layers 11, the first metal layers 13, and the sacrificial layers 12 may be alternately deposited to form a third stack structure.

The third stack structure may be formed to be symmetrical to the first stack structure. Thus, the interlayer insulating layers 11 may be further formed at the top of the third stack structure.

In the third stack structure, the first metal layers 13 may be formed at interfaces between the interlayer insulating layers 11 and the sacrificial layers 12. The number of stacks of the interlayer insulating layers 11 and the sacrificial layers 12 may correspond to the number of drain select transistors included in a single cell string (see FIG. 1). Although the number of drain select transistors may be 5 in the illustrated embodiment, the embodiments of the present disclosure are not limited thereto.

In some embodiments, the third stack structure may be formed by using the same chamber used to form the first and second stack structures, and by using the same method used to form the second stack structure.

Referring to FIG. 6D, a channel hole is formed penetrating the first to third stack structures by etching the interlayer insulating layers 11, the first metal layers 13, and the sacrificial layers 12 included in the first to third stack structures. A dry etching process may be performed to form the channel hole. The channel hole may have various shapes, such as a circle, an oval, a square, a rectangle, and a polygon.

Subsequently, a blocking insulating layer 15, a data storage layer 16, and a tunnel insulating layer 17 may be formed on a sidewall of the channel hole. The blocking insulating layer 15, the data storage layer 16, and the tunnel insulating layer 17 may be sequentially and conformally deposited on the sidewall of the channel hole.

The blocking insulating layer 15 may include a single layer or multiple layers. The blocking insulating layer 15 may include a silicon oxide (e.g., SiO₂) layer or a silicon oxide/metal oxide (e.g., aluminum oxide, Al₂O₃) layer.

The data storage layer 16 may include a silicon nitride (e.g., Si₃N₄) layer.

The tunnel insulating layer 17 may include an oxide (e.g., silicon oxide, SiO₂) layer or metal organic frameworks (MOF) layer.

Subsequently, a channel layer 18 may be formed on the tunnel insulating layer 17. The channel layer 18 may be conformally deposited on the tunnel insulating layer 17.

The channel layer 18 may include a poly-silicon layer. Metal-Induced Lateral Crystallization (MILC) may be used to form the channel layer 18.

Meanwhile, the channel layer 18, the tunnel insulating layer 17, the data storage layer 16, and the blocking insulating layer 15 may be formed in various structures.

In some embodiments, at least one of the blocking insulating layer 15, the data storage layer 16, and the tunnel insulating layer 17 may be disposed in pocket areas in which the sacrificial layers 12 are recessed. To this end, an isotropic etching process may be additionally performed on the sacrificial layers 12 after the channel hole is formed, and etch back process(es) may be additionally performed to form at least one of the blocking insulating layer 15, the data storage layer 16, and the tunnel insulating layer 17 in the pocket areas.

Subsequently, a gap-filling layer 19 may be formed to fill the remaining channel hole. If the channel layer 18 is formed as a full channel, the forming of the gap-fillng layer 19 may be omitted.

Then, the sacrificial layers 12 may be selectively removed (or exhumed). For example, the sacrificial layers 12 may be removed by an isotropic etching process.

Finally, second metal layers 14 may be formed to fill an area from which the sacrificial layers 12 are removed. That is, the second metal layers 14 replaces the sacrificial layers 12. The fist metal layers 14 may have a high work function (e.g., 4.5 eV or higher). For example, the fist metal layers 14 include one of TiN, TiAlN, TiN/W, TaN, HfN, Molybdenum (Mo), Ruthenium (Ru), and a combination thereof.

The first and second metal layers 12 and 14 may serve as gate electrodes (i.e., source select lines in the first stack structure, word lines in the second stack structure, drain select lines in the third stack structure).

As a result, the word lines may be formed of the second metal layer 14 having a high work function for less back-tunneled electrons during an erase operation, and the source/drain select lines may be formed of the first and second metal layers 12 and 14 having a low work function for strong GIDL generation during an erase operation.

According to the above-described embodiments of the present disclosure, a metal such as Lanthanum (La) is added to the gate electrodes of source/drain transistors enables weak dipole formation and a low work function characteristics to improve the GIDL generation during an erase operation. Also, electrons from word lines of memory cells can minimize back-tunneling during an erase operation through strong dipole formation and a high work function characteristics. Furthermore, the fabrication process may be proceeded in the same way as the existing cell formation process without complexity. Thus, the erase operation characteristics of a three-dimensional semiconductor memory device can be dramatically improved.

While the embodiments of the present disclosure described a case where a low work function metal is applied to both the source select line(s) and the drain select line(s), a low work function metal may be only one of the source select line(s) and the drain select line(s) depending on a design.

While the embodiments of the present disclosure contain many specifics, these should not be construed as limitations on the scope of the present disclosure or of what may be claimed, but rather as descriptions of features that may be specific to particular embodiments of the present disclosure. Certain features that are described in the context of separate embodiments can also be implemented in combination to form a single embodiment. Conversely, various features that are described in the context of a single embodiment can also be implemented in multiple embodiments separately or in any suitable sub-combination. Moreover, although features may be described above as acting in certain combinations, one or more features from a combination can in some cases be excised from the combination, and the combination may be directed to a sub-combination or variation of a sub-combination.

Similarly, while operations are depicted in the drawings in a particular order, this should not be understood as requiring that such operations be performed in the particular order shown or in sequential order, or that all illustrated operations be performed, to achieve desirable results. Moreover, the separation of various system components in the embodiments described in the present disclosure should not be understood as requiring such separation in all embodiments.

Only a few implementations and embodiments are described and other implementations, embodiments, enhancements and variations can be made based on what is described and illustrated in the present disclosure. Furthermore, the embodiments may be combined to form additional embodiments.

What is claimed is:

1. A method of fabricating a three-dimensional semiconductor memory device, the method comprising:
forming first interlayer insulating layers and first sacrificial layers alternately stacked on a substrate to form a first stack structure, while forming first metal layers having a first work function at interfaces between the first interlayer insulating layers and the first sacrificial layers;
forming a second interlayer insulating layers and a second sacrificial layers alternately stacked on the first stack structure to form a second stack structure;
forming a third interlayer insulating layers and a third sacrificial layers alternately stacked on the second stack structure to form a third stack structure, while forming second metal layers having the first work function at interfaces between the third interlayer insulating layers and the third sacrificial layers;
forming a channel hole penetrating the first to third stack structures;
forming a memory layer and a channel layer in the channel hole; and
replacing the first to third sacrificial layers with third metal layers having a second work function higher than the first work function.

2. The method of claim 1, wherein each of the first metal layers and the second metal layers includes Lanthanum (La) or La-containing material.

3. The method of claim 1, each of the first metal layers and the second metal layers includes molybdenum nitride (MoN) or MoN-containing material.

4. The method of claim 2, wherein the third metal layers includes at least one of TiN, TiAlN, TiN/W, TaN, HfN, Molybdenum (Mo), and Ruthenium (Ru).

5. The method of claim 1, wherein:
the first metal layers and the third metal layers included in the first stack structure serve as source select lines;
the third metal layers included in the second stack structure serve as word lines; and
the second metal layers and the third metal layers included in the third stack structure serve as drain select lines.

6. The method of claim 1, further comprising, after the forming of the memory layer and the channel layer, forming a gap-filling layer to fill a remaining space of the channel hole.

7. The method of claim 1, wherein the memory layer includes a blocking insulating layer, a data storage layer, and a tunnel insulating layer.

8. A three-dimensional memory device comprising:
a plurality of interlayer insulating layers and a plurality of gate electrodes, which are alternately stacked to form a stack structure; and
a channel vertically disposed within the stack structure,
wherein each of gate electrodes disposed in at least one of a source select transistor area and a drain select transistor area, among the plurality of gate electrodes includes a first metal and a second metal,
wherein each of gate electrodes disposed in a memory cell area, among the plurality of gate electrodes includes the second metal, and
wherein the first metal has a work function lower than a work function of the second metal.

9. The three-dimensional memory device of claim 8, wherein the first metal includes Lanthanum (La) or La-containing material.

10. The three-dimensional memory device of claim 8, wherein the first metal includes molybdenum nitride (MoN) or MoN-containing material.

11. The three-dimensional memory device of claim 9, wherein the second metal includes at least one of TiN, TiAlN, TiN/W, TaN, HfN, Molybdenum (Mo), and Ruthenium (Ru).

12. A method of fabricating a three-dimensional semiconductor memory device, the method comprising:
forming first interlayer insulating layers and first sacrificial layers alternately stacked on a substrate to form a first stack structure, while forming first metal layers having a first work function at interfaces between the first interlayer insulating layers and the first sacrificial layers;
forming a second interlayer insulating layers and a second sacrificial layers alternately stacked on the first stack structure to form a second stack structure;
forming a channel hole penetrating the first and second stack structures;
forming a memory layer and a channel layer in the channel hole; and
replacing the first and second sacrificial layers with second metal layers having a second work function higher than the first work function.

13. The method of claim 12, wherein the first metal layers includes Lanthanum (La) or La-containing material.

14. The method of claim 12, the first metal layers includes molybdenum nitride (MoN) or MoN-containing material.

15. The method of claim 13, wherein the second metal layers includes at least one of TiN, TiAlN, TiN/W, TaN, HfN, Molybdenum (Mo), and Ruthenium (Ru).

16. The method of claim 12, wherein:
the first metal layers and the second metal layers included in the first stack structure serve as source select lines; and
the second metal layers included in the second stack structure serve as word lines or drain select lines.

17. A method of fabricating a three-dimensional semiconductor memory device, the method comprising:
forming first interlayer insulating layers and first sacrificial layers alternately stacked on a substrate to form a first stack structure;
forming second interlayer insulating layers and second sacrificial layers alternately stacked on a substrate to form a second stack structure, while forming first metal layers having a first work function at interfaces between the second interlayer insulating layers and the second sacrificial layers;
forming a channel hole penetrating the first and second stack structures;
forming a memory layer and a channel layer in the channel hole; and
replacing the first and second sacrificial layers with second metal layers having a second work function higher than the first work function.

18. The method of claim 17, wherein the first metal layers includes Lanthanum (La) or La-containing material.

19. The method of claim 17, the first metal layers includes molybdenum nitride (MoN) or MoN-containing material.

20. The method of claim 18, wherein the second metal layers includes at least one of TiN, TiAlN, TiN/W, TaN, HfN, Molybdenum (Mo), and Ruthenium (Ru).

21. The method of claim 17, wherein:
the second metal layers included in the first stack structure serve as source select lines or word lines; and
the first metal layers and the second metal layers included in the second stack structure serve as drain select lines.
